(19) United States
(12) Patent Application Publication
(10) Pub. No.: US 2026/0213730 A1
(43) Pub. Date: Jul. 23, 2026

(54) ACOUSTIC WAVE FILTER DEVICE AND METHOD OF MANUFACTURING ACOUSTIC WAVE FILTER DEVICE

(71) Applicant: Murata Manufacturing Co., Ltd., Nagaokakyo-shi (JP)

(72) Inventor: Takashi IWAMOTO, Nagaokakyo-shi (JP)

(21) Appl. No.: 19/572,033

(22) Filed: Mar. 19, 2026

Related U.S. Application Data
(63) Continuation of application No. PCT/JP2024/037058, filed on Oct. 17, 2024.

(30) Foreign Application Priority Data
Oct. 17, 2023 (JP) 2023-179126

(51) Int. Cl. H03H 9/56; H03H 3/02; H03H 9/05; H03H 9/10; H03H 9/17; H03H 9/70

(52) U.S. Cl. CPC H03H 9/562; H03H 3/02; H03H 9/0523; H03H 9/105; H03H 9/173; H03H 9/178; H03H 9/564; H03H 9/568; H03H 9/706; H03H 2003/021

(57) ABSTRACT

An acoustic wave filter device including resonators includes a support including a support substrate with a thickness in a first direction, first and second piezoelectric layers located on a main surface of the support at different positions, and functional electrodes of the resonators on the first piezoelectric layer and the second piezoelectric layer. The resonators include a first resonator in the first piezoelectric layer and a second resonator in the second piezoelectric layer. The first piezoelectric layer includes first and second piezoelectric films that are laminated. Polarization directions of the first and second piezoelectric films differ from each other. A number of piezoelectric films included in the second piezoelectric layer is smaller than a number of the piezoelectric films included in the first piezoelectric layer.

### CROSS REFERENCE TO RELATED APPLICATIONS

This application claims the benefit of priority to Japanese Patent Application No. 2023-179126 filed on Oct. 17, 2023 and is a Continuation Application of PCT Application No. PCT/JP 2024/037058 filed on Oct. 17, 2024. The entire contents of each application are hereby incorporated herein by reference.

### BACKGROUND OF THE INVENTION

### 1. Field of the Invention

The present invention relates to acoustic wave filter devices and methods of manufacturing acoustic wave filter devices.

### 2. Description of the Related Art

Japanese Unexamined Patent Application Publication No. 2007-036915 discloses a thin-film resonant device including a piezoelectric layer between an upper electrode and a lower electrode. The thin-film resonant device is a high-order mode thin-film resonant device including the piezoelectric layer in which a first piezoelectric thin film oriented in a direction parallel to the surface of the piezoelectric thin film is laminated with a second piezoelectric thin film that includes the same material and has the same thickness as the first piezoelectric thin film and is oriented in a direction 180° different from that of the first piezoelectric thin film so as to have a polarization direction 180° different from that of the first piezoelectric thin film.

The thin-film resonant device disclosed in Japanese Unexamined Patent Application Publication No. 2007-036915 has advantages that reduce or prevent, for example, spurious emissions because the piezoelectric layer includes two piezoelectric thin films as compared with a piezoelectric layer including one piezoelectric thin film. On the other hand, since the distance between the upper electrode and the lower electrode increases when the piezoelectric layer includes two piezoelectric thin films, the areas of the upper electrode and the lower electrode need to be larger than those in the case of one piezoelectric thin film to obtain the same capacitance between the upper and lower electrodes. Accordingly, when the filter device including a resonant circuit with the same structure as in the case of one piezoelectric thin film is produced by using a resonant device with two piezoelectric thin films, the filter device becomes larger.

### SUMMARY OF THE INVENTION

Example embodiments of the present invention provide small-sized acoustic wave filter devices each with improved resonance characteristics.

According to an example embodiment of the present invention, an acoustic wave filter device including a plurality of resonators includes a support including a support substrate with a thickness in a first direction, a first piezoelectric layer on a main surface of the support, a second piezoelectric layer at a different position from the first piezoelectric layer on the main surface of the support, and functional electrodes of the plurality of resonators, the functional electrodes being provided on the first piezoelectric layer and the second piezoelectric layer, in which the plurality of resonators include a first resonator in the first piezoelectric layer and a second resonator in the second piezoelectric layer, the first piezoelectric layer includes a first piezoelectric film and a second piezoelectric film laminated on the first piezoelectric film, a polarization direction of the first piezoelectric film differs from a polarization direction of the second piezoelectric film, and a number of piezoelectric films included in the second piezoelectric layer is less than a number of the piezoelectric films included in the first piezoelectric layer.

According to an example embodiment of the present invention, a method of manufacturing an acoustic wave filter device including a plurality of resonators, the method includes forming a first chip including a first piezoelectric layer and a first temporary substrate, forming a second chip including a second piezoelectric layer and a second temporary substrate, joining the first chip and the second chip to a main surface of a support including a support substrate with a thickness in a first direction, and removing the first and second temporary substrates of the first chip and the second chip joined to the support, in which the plurality of resonators include a first resonator in the first piezoelectric layer and a second resonator in the second piezoelectric layer, the first piezoelectric layer includes a first piezoelectric film and a second piezoelectric film laminated on the first piezoelectric film, a polarization direction of the first piezoelectric film differs from a polarization direction of the second piezoelectric film, and a number of piezoelectric films included in the second piezoelectric layer is less than a number of the piezoelectric films included in the first piezoelectric layer.

According to example embodiments of the present invention, small-sized acoustic wave filter devices each with improved resonance characteristics are provided.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic cross-sectional view illustrating an example of an acoustic wave filter device according to an example embodiment of the present invention.

FIG. 2 is a schematic enlarged cross-sectional view of region II in FIG. 1.

FIG. 3 is a schematic enlarged cross-sectional view of region III in FIG. 1.

FIG. 4 is a schematic plan view illustrating an example of functional electrodes according to an example embodiment of the present invention.

FIG. 5 is a schematic plan view illustrating an example of the acoustic wave filter device according to the example embodiment of the present invention.

FIG. 6 is a circuit diagram of a transmission filter of the acoustic wave filter device in FIG. 5.

FIG. 7 is a circuit diagram of a reception filter of the acoustic wave filter device in FIG. 5.

FIG. 8 is a cross-sectional view illustrating a portion of another example of an acoustic wave filter device according to an example embodiment of the present invention.

FIG. 9 is a schematic cross-sectional view illustrating a first chip and a second chip according to an example embodiment of the present invention.

FIG. 10 is a schematic process diagram for describing an example of a first chip formation process in a method of manufacturing an acoustic wave filter device according to an example embodiment of the present invention.

FIG. 11 is a schematic process diagram for describing an example of a second chip formation process in a method of manufacturing an acoustic wave filter device according to an example embodiment of the present invention.

FIG. 12 is a schematic cross-sectional view for describing a joint process in a method of manufacturing an acoustic wave filter device according to an example embodiment of the present invention.

FIG. 13 is a schematic cross-sectional view for describing a temporary substrate removal process in a method of manufacturing an acoustic wave filter device according to an example embodiment of the present invention.

FIG. 14 is a schematic cross-sectional view for describing an upper electrode formation process in a method of manufacturing an acoustic wave filter device according to an example embodiment of the present invention.

FIG. 15 is a schematic cross-sectional view for describing a first wiring electrode formation process in a method of manufacturing an acoustic wave filter device according to an example embodiment of the present invention.

FIG. 16 is a schematic cross-sectional view for describing a space portion formation process in a method of manufacturing an acoustic wave filter device according to an example embodiment of the present invention.

FIG. 17 is a schematic cross-sectional view for describing a second wiring formation process in a method of manufacturing an acoustic wave filter device according to an example embodiment of the present invention.

FIG. 18 is a schematic cross-sectional view for describing a support frame formation process in a method of manufacturing an acoustic wave filter device according to an example embodiment of the present invention.

FIG. 19 is a schematic cross-sectional view for describing a sealing process in a method of manufacturing an acoustic wave filter device according to an example embodiment of the present invention.

FIG. 20 is a schematic cross-sectional view for describing a bump formation process in a method of manufacturing an acoustic wave filter device according to an example embodiment of the present invention.

FIG. 21 is a schematic cross-sectional view illustrating an acoustic wave filter device according to an example of the example embodiment of the present invention.

### DETAILED DESCRIPTION OF THE EXAMPLE EMBODIMENTS

Example embodiments of the present disclosure will be described in detail below with reference to the drawings. The present disclosure is not limited by the example embodiments described herein. The example embodiments described in the present disclosure are exemplary, and, in modifications and second and subsequent example embodiments in which partial replacement or combination of structures is possible between different example embodiments, only differences from the present example embodiment will be described, and matters common to the present example embodiment will not be described. In particular, the same operations and advantageous effects achieved by the same or corresponding structure will not be described sequentially for each example embodiment.

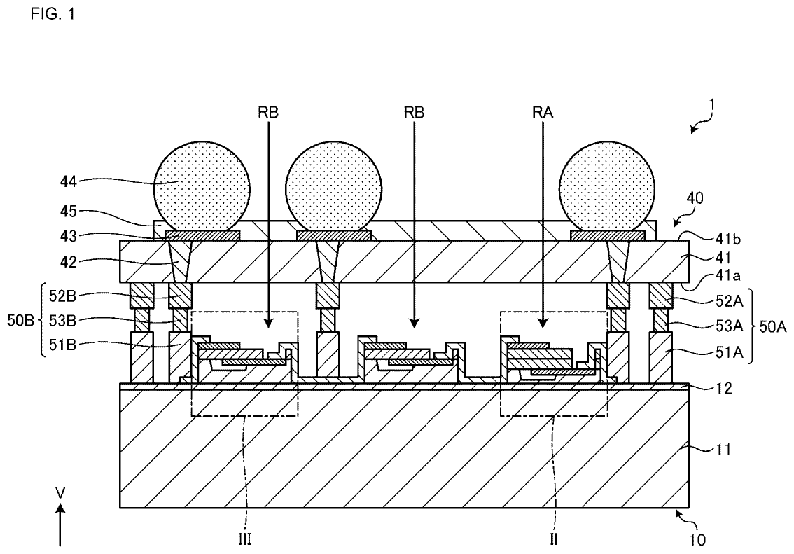

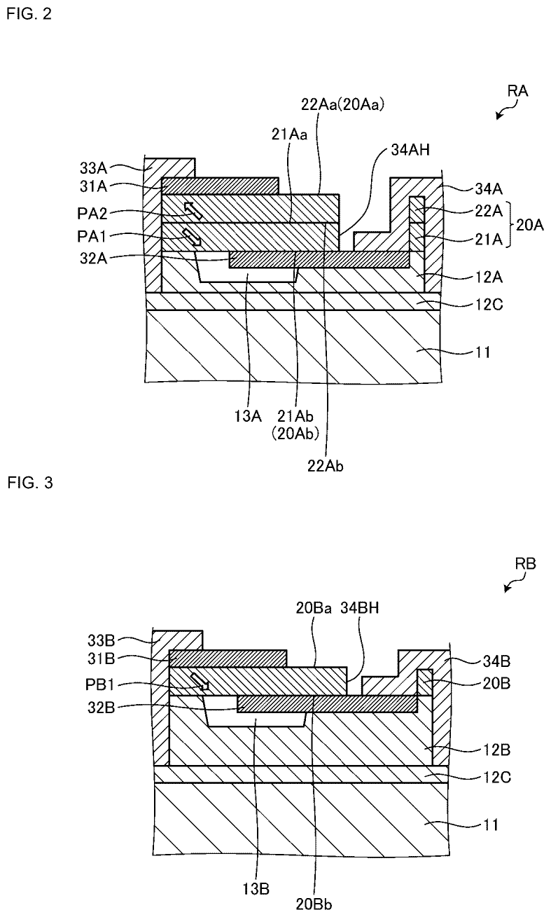

FIG. 1 is a schematic cross-sectional view illustrating an example of an acoustic wave filter device according to an example embodiment of the present invention. FIG. 2 is a schematic enlarged cross-sectional view of region II in FIG. 1. FIG. 3 is a schematic enlarged cross-sectional view of region III in FIG. 1. An acoustic wave filter device 1 according to the present example embodiment is an acoustic wave filter device that includes a plurality of resonators. As illustrated in FIGS. 1 to 3, the acoustic wave filter device 1 includes a support 10, a first piezoelectric layer 20A, a second piezoelectric layer 20B, upper electrodes 31A and 31B, lower electrodes 32A and 32B, wiring electrodes 33A, 34A, 33B, and 34B, a cover 40, support frames 50A, and extended electrodes 50B. In this specification, the upper electrodes 31A and 31B and the lower electrodes 32A and 32B are examples of the “functional electrodes of the resonators”. In the following description, the thickness direction of the support 10 is referred to as a V direction. In this specification, the V direction corresponds to the “first direction”.

The plurality of resonators of the acoustic wave filter device 1 include a first resonator RA and a second resonator RB. The first resonator RA and the second resonator RB are piezoelectric elements that utilize bulk waves, that is, bulk acoustic wave (BAW) elements. One first resonator RA and two second resonators RB are provided so as to be electrically connected to each other in the example embodiment in FIG. 1, but this is only an example, and the present invention is not limited to this. Details on the number, the disposition, and the connection of resonators included in the acoustic wave filter device 1 will be described later.

The first resonator RA is provided in the first piezoelectric layer 20A. In this specification, when the resonator is provided in the first piezoelectric layer 20A, the functional electrodes of the resonator are provided in the first piezoelectric layer 20A. The functional electrodes of the first resonator RA are the upper electrode 31A and the lower electrode 32A. That is, the first resonator RA operates by exciting the first piezoelectric layer 20A in the region sandwiched between the upper electrode 31A and the lower electrode 32A. In the following description, the region in which the upper electrode 31A and the lower electrode 32A overlap each other in plan view in the V direction may be referred to as an excitation region of the first resonator RA.

The second resonators RB are provided in the second piezoelectric layer 20B. In this specification, when the resonators are provided in the second piezoelectric layer 20B, the functional electrodes of the resonators are provided in the second piezoelectric layer 20B. The functional electrodes of each of the second resonators RB are the upper electrode 31B and the lower electrode 32B. That is, the second resonator RB operates by exciting the second piezoelectric layer 20B in the region sandwiched between the upper electrode 31B and the lower electrode 32B. In the following description, the region in which the upper electrode 31B and the lower electrode 32B overlap each other may be referred to as an excitation region of the second resonator RB.

The support 10 includes a support substrate 11. The support substrate 11 has a thickness in the V direction. The support substrate 11 is made of silicon (Si), quartz, or the like, for example. In the present example embodiment, the support 10 further includes an intermediate layer 12. The intermediate layer 12 is provided on a main surface of the support substrate 11. In the example embodiment in FIG. 1, the intermediate layer 12 includes an intermediate layer 12A, an intermediate layer 12B, and an intermediate layer 12C provided over the entire or substantially the entire main surface of the support substrate 11. The intermediate layer 12C is bonded to the intermediate layers 12A and 12B. As a result, the first piezoelectric layer 20A and the second piezoelectric layer 20B are joined to the support substrate 11. The intermediate layers 12A and 12B will be described later.

The first piezoelectric layer 20A is a planar layer with a thickness in the V direction. The first piezoelectric layer 20A includes a first main surface 20Aa and a second main surface 20Ab. The first piezoelectric layer 20A is provided on the main surface of the support 10 via the intermediate layer 12A, which will be described later. The film thickness of the first piezoelectric layer 20A is not particularly limited but is preferably, for example, about 1 μm or less. As a result, good resonance characteristics can be obtained.

The first piezoelectric layer 20A includes a first piezoelectric film 21A and a second piezoelectric film 22A. The second piezoelectric film 22A is laminated on the first piezoelectric film 21A in the V direction to form a multilayer body. The first piezoelectric film 21A includes a first main surface 21Aa and a second main surface 21Ab. The second piezoelectric film 22A includes a first main surface 22Aa and a second main surface 22Ab. In the example embodiment in FIG. 2, the first main surface 22Aa of the second piezoelectric film corresponds to the first main surface 20Aa of the first piezoelectric layer 20A. The second main surface 21Ab of the first piezoelectric film corresponds to the second main surface 20Ab of the first piezoelectric layer 20A. In addition, the multilayer body is formed by performing joining such that the first main surface 21Aa of the first piezoelectric film 21A faces the second main surface 22Ab of the second piezoelectric film 22A.

In the present example embodiment, the first piezoelectric film 21A and the second piezoelectric film 22A are preferably substrates made of a single crystal capable of exciting bulk waves, such as, for example, lithium niobate (LiNbO₃), lithium tantalate (LiTaO₃), or quartz. As a result, since the crystal orientation of the piezoelectric body can be set to achieve desired filter characteristics, good filter characteristics can be obtained. On one hand, when a material oriented in only one axis, such as an aluminum nitride (AlN) material or a gallium nitride (GaN) material, for example, is used as a piezoelectric body, the design flexibility for the acoustic wave filter device is lower and advantageous effects on the filter characteristics obtained by laminating the first piezoelectric film and the second piezoelectric film together is also limited as compared to the case in which piezoelectric bodies made of single crystals are laminated together, the desired characteristics of the filter device are not necessarily obtained. In the present example embodiment, the first piezoelectric film 21A and the second piezoelectric film 22A are made of the same material and have the same or substantially the same thickness. In the present disclosure, “being made of the same material” refers to “being made of a substance represented by a single experimental formula”.

The polarization direction of the first piezoelectric film 21A differs from the polarization direction of the second piezoelectric film 22A. Here, a difference between the polarization directions means a difference between polarization orientations. In the present example embodiment in FIG. 2, a polarization orientation PA1 of the first piezoelectric film 21A is a direction obtained by rotating a polarization orientation PA2 of the second piezoelectric film 22A by about 180°. As a result, the coupling coefficient of a main mode can be maintained large.

The polarization directions of the first piezoelectric film 21A and the second piezoelectric film 22A can be observed by crystal structure analysis with X-ray diffraction and a scanning probe microscopy (SPM), for example. Specifically, for each of the first piezoelectric film 21A and the second piezoelectric film 22A, the crystal orientations of the piezoelectric films are identified in accordance with an X-ray diffraction image, and the similarity or difference in the polarization orientations of the first piezoelectric film 21A and the second piezoelectric film 22A can be measured in accordance with, for example, a piezo response microscope (PRM) image of a cross-section in the V direction.

The first piezoelectric layer 20A includes a through-hole 20AH that communicates with a space portion 13A. The through-hole 20AH is disposed at a position that overlaps the space portion 13A in plan view in the V direction. The through-hole 20AH is provided at a position that overlaps the side wall of the space portion 13A in the example embodiment in FIG. 2, but the present invention is not limited to this example, and the through-hole 20AH may also be provided so as to pass through the upper electrode 31A and the lower electrode 32A as long as the through-hole 20AH is provided at a position that overlaps the space portion 13A.

In the example embodiment in FIG. 2, an opening window 34AH is provided in the first piezoelectric layer 20A. The opening window 34AH is provided at a position that overlaps the lower electrode 32A and does not overlap the space portion 13A. As a result, since the lower electrode 32A is exposed, a wiring line can be extended toward the first main surface 20Aa of the first piezoelectric layer 20A. It should be noted that the shape of the opening window 34AH is only an example and not limited to this.

The second piezoelectric layer 20B is a planar layer with a thickness in the V direction. The second piezoelectric layer 20B includes a first main surface 20Ba and a second main surface 20Bb. The second piezoelectric layer 20B is provided on the main surface of the support 10 via the intermediate layer 12B, which will be described later. The second piezoelectric layer 20B is provided at a different position from the first piezoelectric layer 20A. In other words, the second piezoelectric layer 20B is provided at a position that is not in contact with the first main surface 20Aa or the second main surface 20Bb of the first piezoelectric layer 20A. The film thickness of the second piezoelectric layer 20B is not particularly limited but is preferably, for example, about 1 μm or less. As a result, good resonance characteristics can be obtained.

In the example embodiment illustrated in FIG. 3, the second piezoelectric layer 20B is a single-layer substrate made of a single crystal capable of exciting bulk waves, such as lithium niobate (LiNbO₃), lithium tantalate (LiTaO₃), or quartz, for example. That is, the second piezoelectric layer 20B can be a layer including a single piezoelectric film. In the example embodiment in FIG. 3, a polarization orientation PB1 of the second piezoelectric layer 20B is the same or substantially the same as that of the first piezoelectric film 21A of the first piezoelectric layer 20A, but this is only an example, and the present invention is not particularly limited to this example.

The second piezoelectric layer 20B includes a through-hole 20BH that communicates with a space portion 13B. Similarly to the through-hole 20AH of the first piezoelectric layer 20A, the through-hole 20BH is disposed at a position that overlaps the side wall of the space portion 13B. The through-hole 20BH is provided so as to pass through the upper electrode 31B and the lower electrode 32B in the example embodiment in FIG. 2, but the present invention is not limited to this example, and the through-hole 20BH may also be provided so as not to pass through the upper electrode 31B and the lower electrode 32B as long as the through-hole 20BH is provided at a position that overlaps the space portion 13B.

In the example embodiment in FIG. 3, an opening window 34BH is provided in the second piezoelectric layer 20B. The opening window 34BH is provided at a position that overlaps the lower electrode 32B and does not overlap the space portion 13B. As a result, since the lower electrode 32B is exposed, a wiring line can be extended toward the first main surface 20Ba of the second piezoelectric layer 20B. The shape of the opening window 34BH is only an example and not limited to this.

The upper electrode 31A is provided on the first main surface 20Aa of the first piezoelectric layer 20A. The upper electrode 31B is provided on the first main surface 20Ba of the second piezoelectric layer 20B. The lower electrode 32A is provided on the second main surface 20Ab of the first piezoelectric layer 20A. The lower electrode 32B is provided on the second main surface 20Bb of the second piezoelectric layer 20B. The upper electrodes 31A and 31B and the lower electrodes 32A and 32B are each made of a metal, such as, for example, aluminum (Al), platinum (Pt), copper (Cu), tungsten (W), or molybdenum (Mo) or an alloy thereof. The upper electrodes 31A and 31B and the lower electrodes 32A and 32B may each include a close contact layer made of titanium (Ti), a nickel-chromium alloy (NiCr), or the like, for example.

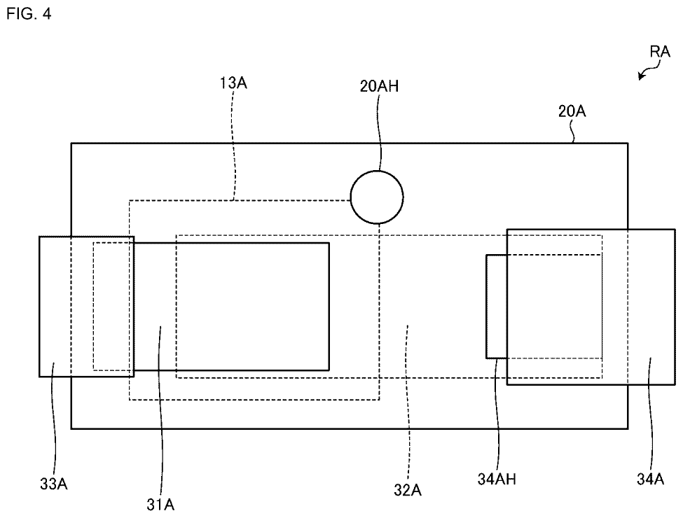

FIG. 4 is a schematic plan view illustrating an example of the functional electrodes according to the present example embodiment. More specifically, FIG. 4 is a plan view illustrating the upper electrode 31A and the lower electrode 32A, which are the functional electrodes of the first resonator RA. Here, the upper electrode 31A and the lower electrode 32A will be described in detail with reference to FIG. 4. In the present example embodiment, the structures of the upper electrode 31B and the lower electrode 32B, which are the functional electrodes of the second resonator RB, are the same or substantially the same as the structures of the upper electrode 31A and the lower electrode 32A, which are the functional electrodes of the first resonator RA, the descriptions thereof are omitted.

As illustrated in FIG. 4, the upper electrode 31A and the lower electrode 32A are, for example, band-shaped electrodes. In plan view in the V direction, a portion of the upper electrode 31A overlaps a portion of the lower electrode 32A. In other words, the first piezoelectric layer 20A includes a region that is sandwiched between the upper electrode 31A and the lower electrode 32A. As a result, a bulk wave propagates in the region between the upper electrode 31A and the lower electrode 32A. That is, the first piezoelectric layer 20A, which is the region between the upper electrode 31A and the lower electrode 32A, corresponds to the excitation region of the first resonator RA. The shapes of the upper electrode 31A and the lower electrode 32A are only examples and the present invention is not limited to the examples.

The intermediate layer 12A is provided on the second main surface 20Ab of the first piezoelectric layer 20A. The intermediate layer 12B is provided on the second main surface 20Bb of the second piezoelectric layer 20B. The intermediate layers 12A and 12B are made of a material with a lower dielectric constant than the materials of the support substrate 11, the first piezoelectric layer 20A, and the second piezoelectric layer 20B and are made of, for example, a dielectric, such as silicon oxide.

The intermediate layer 12A includes the space portion 13A. In the example embodiment in FIG. 2, the space portion 13A is the internal space of a recessed portion provided in a portion of the intermediate layer 12A close to the first piezoelectric layer 20A. The space portion 13A is provided as to overlap the excitation region of the first resonator RA in plan view in the V direction. As a result, a bulk wave caused by driving the first resonator RA is reflected by the space portion 13A.

The intermediate layer 12B includes the space portion 13B. In the example embodiment in FIG. 3, the space portion 13B is the internal space of a recessed portion provided in a portion of the intermediate layer 12B close to the second piezoelectric layer 20B. The space portion 13B is provided as to overlap the excitation region of the second resonator RB in plan view in the V direction. As a result, a bulk wave caused by driving the second resonator RB is reflected by the space portion 13B.

The wiring electrodes 33A, 34A, 33B, and 34B are wiring lines made of a conductor, such as copper (Cu), for example.

The wiring electrodes 33A and 34A are the extended electrodes of the first resonator RA. The wiring electrode 33A is electrically connected to the upper electrode 31A. The wiring electrode 34A is electrically connected to the lower electrode 32A by passing through the opening window 34AH of the first piezoelectric layer 20A in the V direction. As a result, the upper electrode 31A and the lower electrode 32A are extended to the first main surface 20Aa of the first piezoelectric layer 20A.

The wiring electrodes 33B and 34B are the extended electrodes of the second resonator RB. The wiring electrode 33B is electrically connected to the upper electrode 31B. The wiring electrode 34B is electrically connected to the lower electrode 32B by passing through the opening window 34BH of the second piezoelectric layer 20B in the V direction. As a result, the upper electrode 31B and the lower electrode 32B are extended to the first main surface 20Ba of the second piezoelectric layer 20B.

The cover 40 includes a cover substrate 41. As illustrated in FIG. 1, in the present example embodiment, the cover 40 includes the cover substrate 41, through-electrodes 42, underbump metals 43, solder balls 44, and an insulation layer 45.

The cover substrate 41 is disposed at a position that faces the main surface of the support 10 close to the intermediate layer 12. The cover substrate 41 is made of a semiconductor or a conductor, and is, for example, a silicon substrate. The cover substrate 41 includes a first main surface 41a, which is the main surface close to the support 10, and a second main surface 41b, which is the main surface that faces away from the first main surface 41a.

The through-electrode 42 passes through the cover substrate 41. The through-electrode 42 is made of, for example, Cu. The through-electrode 42 may be a multilayer body including a Ti layer laminated as a close contact layer on a Cu layer in a portion in contact with the cover substrate 41.

The underbump metal 43 is provided on the second main surface 41b of the cover substrate 41. The underbump metals 43 are electrically connected to the through-electrodes 42. In the present example embodiment, the underbump metals 43 are laminated on portions of the through-electrodes 42 close to the second main surface 41b of the cover substrate 41. The underbump metals 43 are each a multilayer body including a Cu layer, a Ni layer, and an Au layer that are plated in this order.

The solder balls 44 are solder spheres that are laminated on the underbump metals 43. The solder balls 44 are, for example, ball grid array (BGA) bumps and are outer terminals of the acoustic wave filter device 1.

The insulation layer 45 is a layer that covers the second main surface 41b of the cover substrate 41. The insulation layer 45 is made of, for example, silicon oxide but is not limited to this. The insulation layer 45 may also be a layer made of an appropriate insulating material, such as, for example, aluminum oxide, aluminum nitride, boron nitride, magnesium oxide, polyimide, solder resist, or the like.

The support frames 50A are provided between the cover 40 and the support 10. As a result, the cover 40 and the support 10 face each other with a space therebetween in the V direction.

The extended electrodes 50B electrically connect the through-electrodes 42 and the functional electrodes of the first resonator RA and the second resonator RB to each other. As a result, the input and output of signals of the first resonator RA and the second resonator RB provided in the support substrate 11 can be performed via the outer terminals (solder balls 44) of the cover 40.

In the present example embodiment, the support frames 50A each include a first land 51A, a second land 52A, and an adhesion layer 53A. The extended electrodes 50B each include a first land 51B, a second land 52B, and an adhesion layer 53B. The first lands 51A and 51B are provided in portions of the support substrate 11 close to the intermediate layer 12. The second lands 52A and 52B are provided at positions that overlap the first lands 51A and 51B in plan view in the V direction. The second lands 52A and 52B are provided on the second main surface 41b of the cover substrate 41. The adhesion layers 53A and 53B are provided between the first lands 51A and 51B and the second lands 52A and 52B in the V direction and join the first lands 51A and 51B and the second lands 52A and 52B to each other. The support frame 50A and the extended electrode 50B are each made of, for example, a metal, an insulator, or the like. More specifically, the first lands 51A and 51B and the second lands 52A and 52B are made of, for example, aluminum (Al), and the adhesion layers 53A and 53B are made of, for example, gold (Au).

The support frame 50A is configured in a linear pattern so as to surround the first resonator RA and the second resonator RB in plan view in the V direction. As a result, since the space between the support 10 and the cover 40 in the V direction is sealed, the first resonator RA and the second resonator RB can be protected from moisture and dust external to the acoustic wave filter device 1.

The ends of the extended electrodes 50B close to the support 10 are connected to the wiring lines (wiring electrodes 33A, 34A, 33B, and 34B) of the first resonator RA and the second resonator RB. In addition, the ends of the extended electrodes 50B close to the cover substrate 41 are connected to the through-electrodes 42. As a result, the components from the solder balls 44 to the first resonator RA and the second resonator RB are electrically connected together.

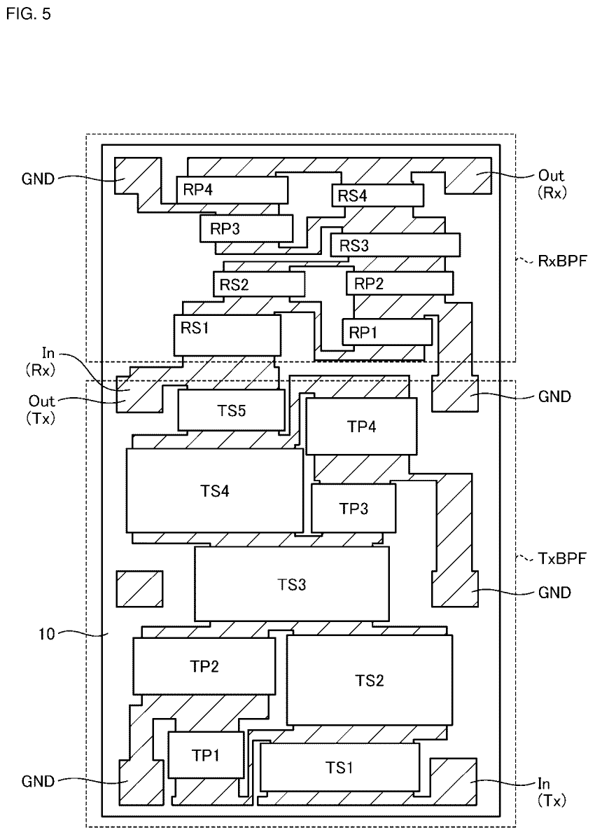

The structure of the acoustic wave filter device 1 according to the present example embodiment will be described in detail below. FIG. 5 is a schematic plan view illustrating an example of an acoustic wave filter device according to an example embodiment. In FIG. 5, the rectangles indicated by TS1 to TS5, TP1 to TP4, RS1 to RS4, and RP1 to RP4 indicate the regions in which the resonators TS1 to TS5, TP1 to TP4, RS1 to RS4, and RP1 to RP4 are respectively disposed. In addition, the hatched portions in FIG. 5 indicate the regions in which wiring lines made of conductors are provided.

As illustrated in FIG. 5, the acoustic wave filter device 1 according to the present example embodiment includes a transmission filter TxBPF and a reception filter RxBPF. In the example embodiment in FIG. 5, an output terminal Out(Tx) of the transmission filter TxBPF and an input terminal In(Rx) of the reception filter RxBPF are electrically connected to each other.

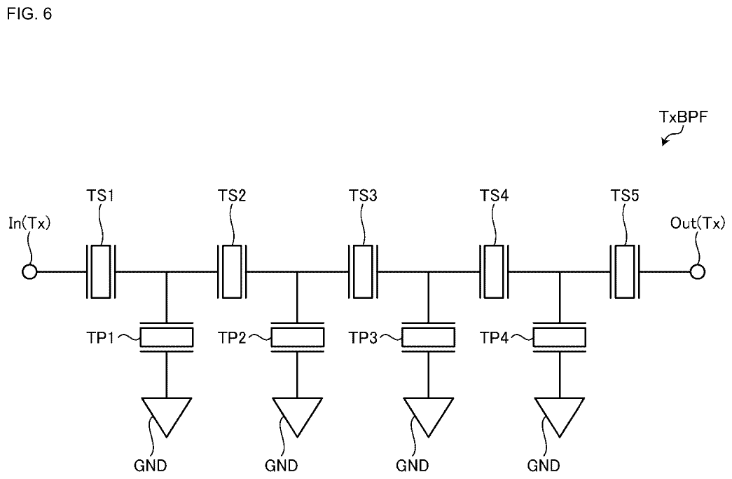

FIG. 6 is a circuit diagram of the transmission filter of the acoustic wave filter device in FIG. 5. As illustrated in FIG. 6, the transmission filter TxBPF is a ladder filter that includes series arm resonators included in series on the signal path (referred to below as the transmission path) from the input terminal In(Tx) to the output terminal Out(Tx) and parallel arm resonators included on the path between nodes on the transmission path and the ground GND. Here, the transmission path is an example of series arms in the present disclosure, and the paths between the nodes on the transmission path and the ground GND are examples of parallel arms in the present disclosure. In FIG. 6, the series arm resonators include the resonators TS1 to TS5. The parallel arm resonators include the resonators TP1 to TP4. One terminal of the resonators TS1 to TS5 is electrically connected to the input terminal In(Tx), and the other terminal is electrically connected to the output terminal Out(Tx). Here, the resonators TS1 to TS5 are electrically connected in series to each other. One terminal of the resonator TP1 is electrically connected to the wiring line that connects the resonator TS1 and the resonator TS2 to each other. One terminal of the resonator TP2 is electrically connected to the wiring line that connects the resonator TS2 and the resonator TS3 to each other. One terminal of the resonator TP3 is electrically connected to the wiring line that connects the resonator TS3 and the resonator TS4 to each other. One terminal of the resonator TP4 is electrically connected to the wiring line that connects the resonator TS4 and the resonator TS5 to each other. The other terminals of the resonators TP1 to TP4 are electrically connected to the ground GND.

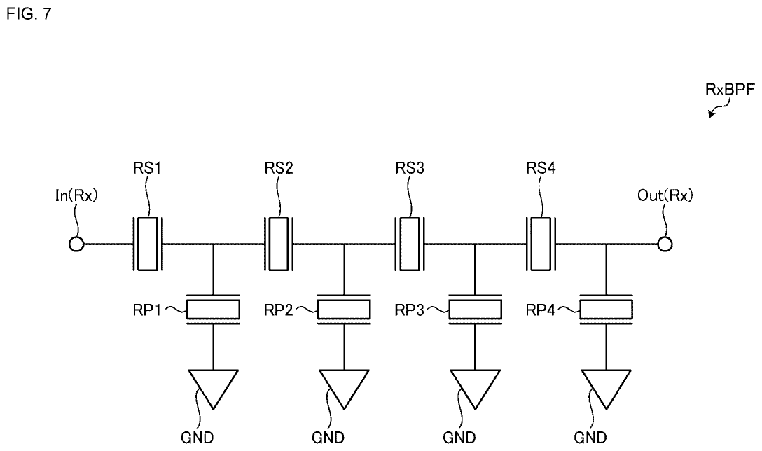

FIG. 7 is a circuit diagram of the reception filter of the acoustic wave filter device in FIG. 5. As illustrated in FIG. 7, the reception filter RxBPF is a ladder filter that includes series arm resonators included in series on the signal path (referred to below as the reception path) from the input terminal In(Rx) to the output terminal Out(Rx) and parallel arm resonators included in the path between nodes in the reception path and the ground GND. Here, the reception path is an example of a series arms in the present disclosure, and the paths between the nodes on the reception path and the ground GND are examples of parallel arms in the present disclosure. In FIG. 7, the series arm resonators include the resonators RS1 to RS4. The parallel arm resonators include the resonators RP1 to RP4. One terminal of the resonators RS1 to RS4 is electrically connected to the input terminal In(Rx), and the other terminal is electrically connected to the output terminal Out(Rx). Here, the resonators RS1 to RS4 are electrically connected in series to each other. One terminal of the resonator RP1 is electrically connected to the wiring line that connects the resonator RS1 and the resonator RS2 to each other. One terminal of the resonator RP2 is electrically connected to the wiring line that connects the resonator RS2 and the resonator RS3 to each other. One terminal of the resonator RP3 is electrically connected to the wiring line that connects the resonator RS3 and the resonator RS4 to each other. One terminal of the resonator RP4 is electrically connected to the wiring line that connects the resonator RS4 and the output terminal Out(Rx) to each other. The other terminals of the resonators RP1 to RP4 are electrically connected to the ground GND.

In the present example embodiment, the first resonator RA is the resonator TS1, provided on the transmission path, that is connected to the input terminal In(Tx) of the transmission filter TxBPF. In this specification, in the resonator connected to the input terminal In(Tx) of the transmission filter TxBPF, no other resonators are present between this resonator and the input terminal In(Tx) of the transmission filter TxBPF. Accordingly, the first piezoelectric layer 20A that includes the first piezoelectric film 21A and the second piezoelectric film 22A is provided in the region that overlaps the resonator TS1 in FIG. 5.

In the example embodiment in FIG. 5, since the first resonator RA, that is, the resonator TS1, is the first stage resonant device from the input terminal In(Tx) of the transmission filter TxBPF, a signal with large power amplified by a power amplifier passes through the first resonator RA. In other words, the highest power of the plurality of resonators is applied to the first resonator RA. Accordingly, the first resonator RA needs to have high electric power handling capability. Since the size of the functional electrodes of the first resonator RA can be increased by configuring the first piezoelectric layer 20A provided with the first resonator RA as a multilayer body including a plurality of piezoelectric films in the present example embodiment, the power per unit area and the power per unit thickness that are applied to the excitation region of the first resonator RA can be reduced. In addition, the heat dissipation by the first piezoelectric layer 20A can be improved. In addition, the thicknesses of the functional electrodes (the upper electrode 31A and the lower electrode 32B) can be increased, and the heat dissipation via the functional electrodes can be improved. This can reduce or prevent a temperature rise during the driving of the acoustic wave filter device 1 and improve the electric power handling capability of the first resonator RA.

In the present example embodiment, the second resonator RB includes the resonators TS2 to TS5, which are provided on the path that connects the resonator TS1 and the output terminal Out(Tx) of the transmission filter TxBPF to each other, the resonators RS1 to RS4, which are provided on the reception path, the resonators TP1 to TP4, which are parallel arm resonators of the transmission filter TxBPF, and the resonators RP1 to RP4, which are the parallel arm resonators of the reception filter RxBPF. Accordingly, the second piezoelectric layer 20B including a single layer is provided in the region that overlaps the resonators TS2 to TS5, RS1 to RS4, TP1 to TP4, and RP1 to RP4 in FIG. 5.

In the example embodiment in FIG. 5, the second resonator RB, which includes the resonators TS2 to TS5, RS1 to RS4, TP1 to TP4, and RP1 to RP4, receives less input power than the first resonator RA. Accordingly, the second resonator RB may have lower electric power handling capability than the first resonator RA. In addition, when the second piezoelectric layer is configured as a multilayer body including the same number of piezoelectric films of the first piezoelectric layer, the thickness of the piezoelectric layer is larger than that of the piezoelectric layer including a single piezoelectric film, and accordingly, the area of the functional electrodes of the second resonator RB needs to be increased to obtain the same capacitance. As a result, an increase in the size of the second resonator RB may make the size of the acoustic wave filter device 1 larger. Accordingly, by making the number of piezoelectric films laminated in the second piezoelectric layer 20B smaller than that in the first piezoelectric layer 20A, the area of the functional electrodes of the second resonator RB that need not have high electric power handling capability can be reduced while the electric power handling capability of the first resonator RA is improved, and accordingly, the size of the acoustic wave filter device 1 can be reduced.

An example of the acoustic wave filter device according to the present example embodiment has been described above, but the acoustic wave filter device according to the present invention is not limited to the present example embodiment described above.

For example, a layer made of a material other than a piezoelectric body may be sandwiched between the first piezoelectric film and the second piezoelectric film. That is, the first main surface of the first piezoelectric film and the second main surface of the second piezoelectric film need not be in contact with each other.

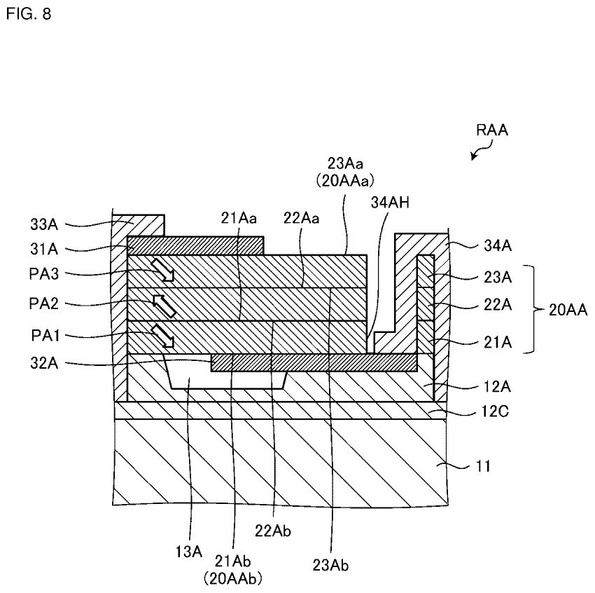

FIG. 8 is a cross-sectional view illustrating a portion of another example of an acoustic wave filter device according to an example embodiment of the present invention. FIG. 8 is a cross-sectional view illustrating a first resonator RAA and corresponds to FIG. 2. As illustrated in FIG. 8, for example, a first piezoelectric layer 20AA may be a multilayer body including three or more piezoelectric films. In the example embodiment in FIG. 8, the first piezoelectric layer 20AA includes the first piezoelectric film 21A, the second piezoelectric film 22A, and a third piezoelectric film 23A. In this case, when the number of piezoelectric films laminated in the second piezoelectric layer is less than that in the first piezoelectric layer 20AA, the second piezoelectric layer may be a multilayer body including a plurality of piezoelectric films, as in the first piezoelectric layer 20A illustrated in FIG. 2. In this case, the polarization directions of the piezoelectric films adjacent to each other in the lamination direction of the piezoelectric films differ from each other. In the example embodiment in FIG. 8, the polarization orientation PA1 of the first piezoelectric film 21A and a polarization orientation PA3 of the third piezoelectric film 23A are rotated about 180° from the polarization orientation PA2 of the second piezoelectric film 22A. As a result, the coupling coefficient of the main mode can be maintained large.

For example, the first resonator may include the resonator with the highest resonant frequency of the plurality of resonators included in the acoustic wave filter device. In this case, the second resonator includes at least one resonator with a lower resonant frequency than the resonator with the highest resonant frequency. Here, when the materials of the piezoelectric films have the same composition between the plurality of resonators, the higher the resonant frequencies of the resonators, the smaller the thickness of one piezoelectric film needs to be. Accordingly, the thicknesses of the piezoelectric films of the first piezoelectric layer concerning the first resonator with the highest resonant frequency needs to be reduced. However, when the thickness of each of the piezoelectric films is reduced, the piezoelectric film may be likely to be broken. In the present example embodiment, by making the number of piezoelectric films laminated in the first piezoelectric layer larger than the number in the second piezoelectric layer, the first piezoelectric layer can be reduced or prevented from being broken. On the other hand, the thicknesses of the piezoelectric films of the second piezoelectric layer concerning the second resonator with a low resonant frequency needs to be increased. Accordingly, the piezoelectric films of the second piezoelectric layer are less likely to be broken than the piezoelectric films of the first piezoelectric layer. In the present example embodiment, by making the number of piezoelectric films laminated in the second piezoelectric layer larger than that in the first piezoelectric layer, the area of the functional electrodes concerning the second resonator can be reduced. As a result, it is possible to reduce or prevent the piezoelectric films of the first piezoelectric layer and the second piezoelectric layer of the acoustic wave filter device from being broken and to reduce the size of the acoustic wave filter device.

For example, the first resonator may include the resonator with the lowest resonant frequency of the plurality of resonators included in the acoustic wave filter device. In this case, the second resonator includes at least one resonator with a higher resonant frequency than the resonator with the lowest resonant frequency. Here, when an acoustic wave filter device that includes the piezoelectric films made of the same material and a resonant circuit with the same or substantially the same structure is manufactured, since the area of the excitation region of the resonator becomes larger as the resonant frequency is reduced, cracks are likely to occur in the piezoelectric films due to thermal stress generated when the acoustic wave filter device operates. In particular, when a material with brittleness, such as LiTaO₃, LiNbO₃, GaN, or AlN, for example, is used as the piezoelectric films, and the difference in the linear expansion coefficients of the excitation electrode and the piezoelectric film is large, cracks are likely to occur. Accordingly, an increase in the number of laminated piezoelectric films made of the same material can increase the film thickness of the piezoelectric layer and reduce or prevent cracks from occurring due to thermal stress. In addition, when the piezoelectric films are made of the same material, it is believed that cracks can be reduced or prevented from occurring because the thermal stress does not increase even when the piezoelectric films are laminated and the stress is distributed. In addition, an increase in the number of laminated piezoelectric films can improve the strength of the resonator and improve the resistance to impacts and the like.

For example, the first resonator may be the resonator that has significant effects on the filter characteristics of the plurality of resonators included in the acoustic wave filter device. Since an increase in the number of laminated piezoelectric films can increase the area of the functional electrodes and reduce the area of the functional electrodes of the second resonator that has small effects on the filter characteristics while the resonance characteristics of the first resonator are enhance, the size of the acoustic wave filter device 1 can be reduced while the filter characteristics are improved.

For example, in the acoustic wave filter device, which is a ladder filter, the parallel arms may connect at least one of the input terminal and the output terminal to the ground. That is, the parallel arm resonator may be directly connected to at least one of the input terminal and the output terminal. Also in this case, since the area of the functional electrodes of the second resonator that need not have high electric power handling capability can be reduced while the electric power handling capability of the first resonator to which large power is input is improved, the size of the acoustic wave filter device can be reduced while the resonance characteristics of the acoustic wave filter device are improved.

As described above, the acoustic wave filter device according to the present example embodiment is an acoustic wave filter device including a plurality of resonators, a support including a support substrate with a thickness in the first direction, a first piezoelectric layer on the main surface of the support, a second piezoelectric layer at a different position from the first piezoelectric layer on the main surface of the support, and functional electrodes of the resonators on the main surfaces of the first piezoelectric layer and the second piezoelectric layer. The plurality of resonators include a first resonator in the first piezoelectric layer and a second resonator in the second piezoelectric layer. The first piezoelectric layer includes a first piezoelectric film and a second piezoelectric film that is laminated on the first piezoelectric film. The polarization direction of the first piezoelectric film differs from the polarization direction of the second piezoelectric film. The number of piezoelectric films included in the second piezoelectric layer is smaller than the number of the piezoelectric films included in the first piezoelectric layer. As a result, since the area of the functional electrodes of the second resonator can be reduced while the resonance characteristics of the first resonator are improved, the size of the acoustic wave filter device can be reduced while the resonance characteristics of the acoustic wave filter device are improved.

Preferably, for example, the first resonator includes the resonator with the highest resonant frequency of the plurality of resonators. The second resonator includes at least one resonator with a lower resonant frequency than the resonator with the highest resonant frequency. Since this can reduce the area of the functional electrodes of the second resonator with a lower resonant frequency while reducing or preventing the first piezoelectric layer due to high frequency from being broken, the size of the acoustic wave filter device can be reduced while the resonance characteristics of the acoustic wave filter device are improved.

In addition, preferably, for example, the first resonator includes the resonator with the lowest resonant frequency of the plurality of resonators. The second resonator includes at least one resonator with a higher resonant frequency than the resonator with the lowest resonant frequency. As a result, cracks in the first piezoelectric layer due to the large area of the excitation region can be reduced.

Preferably, for example, the first resonator includes the resonator to which the largest power is applied of the plurality of resonators. The second resonator includes at least one resonator to which smaller power is applied than the resonator to which the largest power is applied. Since this can increase the size of the functional electrodes of the first resonator that needs to have high electric power handling capability, the power per unit area and the power per unit thickness applied to the excitation region of the first resonator can be reduced, and accordingly, heat dissipation can be improved. This can reduce or prevent a temperature rise during the driving of the acoustic wave filter device and improve the electric power handling capability of the first resonator.

Preferably, for example, the acoustic wave filter device includes a transmission filter and a reception filter. The first resonator is provided on the path that connects the input terminal and the output terminal of the transmission filter to each other and includes the resonator (resonator TS1) connected to the input terminal of the transmission filter. The second resonator includes at least one of the resonators (the resonators TS2 to TS5 or the resonators RP1 to RP4) provided on the path that connects the first resonator and the output terminal of the transmission filter to each other or on the path that connects the input terminal and output terminal of the reception filter to each other.

Preferably, for example, the acoustic wave filter device includes the input terminal, the output terminal, the series arms that connect, to each other, the input terminal and the output terminal, and the parallel arms that connect, to each other, the ground and at least one of the input terminal, the output terminal, or the nodes of the series arms. The first resonator includes at least one of the resonators TS1 to TS5 and RS1 to RS4 provided in the series arms. The second resonator includes at least one of the resonators TP1 to TP4 and RP1 to RP4 provided in the parallel arms. As a result, since the area of the functional electrodes of the second resonator that need not have high electric power handling capability can be reduced while the electric power handling capability of the first resonator to which large power is input is improved, the size of the acoustic wave filter device can be reduced while the resonance characteristics of the acoustic wave filter device are improved.

Preferably, for example, the acoustic wave filter device includes the intermediate layer, made of a dielectric, that is provided between the main surface of the support substrate and the first piezoelectric layer and the second piezoelectric layer. As a result, the intermediate layer is directly joined to the support substrate. Accordingly, as compared to the case in which the substrate including the first piezoelectric layer and the second piezoelectric layer is provided as the support substrate, the profile of the acoustic wave filter device 1 can be reduced, heat more easily escapes to the support substrate, and accordingly, the electric power handling capability can be improved.

More preferably, for example, the material of the intermediate layer has a lower dielectric constant than the materials of the support substrate, the first piezoelectric layer, and the second piezoelectric layer. Since this reduces the parasitic capacitance between the support substrate and the wiring electrode that connects, for example, the first resonator and the second resonator to each other and improves the filter characteristics, the resonance characteristics of the acoustic wave filter device can be improved while the profile of the acoustic wave filter device is reduced.

An example of a method of manufacturing the acoustic wave filter device according to an example embodiment of the present invention will be described below. The method of manufacturing the acoustic wave filter device according to the present example embodiment includes a first chip formation process (steps S11A to S18A), a second chip formation process (steps S11B, S12B, and S15B to S18B), a joint process (step S21), a temporary substrate removal process (step S22), an upper electrode formation process (step S23), a first wiring formation process (step S24), a space portion formation process (step S25), a second wiring formation process (step S26), a support frame formation process (step S27), a sealing process (step S28), and a bump formation process (step S29). In this specification, the first chip formation process (steps S11A to S18A) and the second chip formation process (S11B, S12B, and S15B to S18B) are examples of the chip formation process.

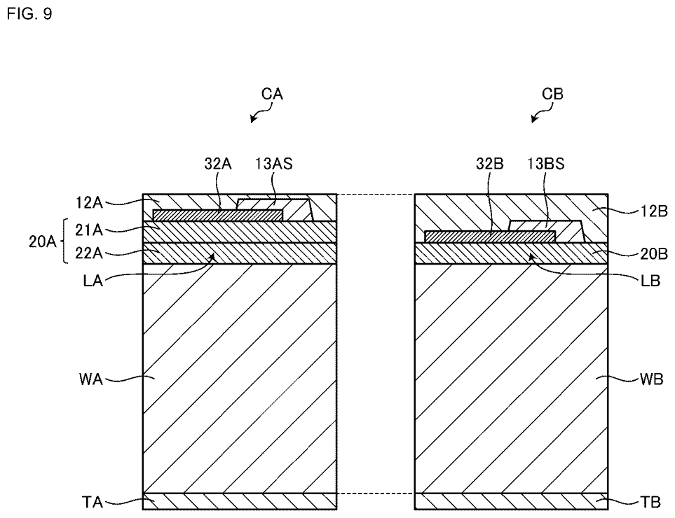

FIG. 9 is a schematic cross-sectional view illustrating a first chip and a second chip according to the present example embodiment. In the following description, a first chip CA includes a temporary substrate WA and a first multilayer film LA formed on the temporary substrate WA, and a second chip CB includes a temporary substrate WB and a second multilayer film LB formed on the temporary substrate WB. Here, the first multilayer film LA includes the first piezoelectric layer 20A, the lower electrode 32A disposed on the first piezoelectric layer 20A, a sacrificial layer 13AS, and the intermediate layer 12A. In addition, the second multilayer film LB includes the second piezoelectric layer 20B, the lower electrode 32B disposed on the second piezoelectric layer 20B, a sacrificial layer 13BS, and the intermediate layer 12B.

The temporary substrates WA and WB define and function as bases up to the joint process of transferring the multilayer film CA and the multilayer film CB to the support substrate 11 and are made of, for example, single-crystal silicon. As illustrated in FIG. 9, the thicknesses of the temporary substrates WA and WB are adjusted such that the thickness of the first chip CA is the same or substantially the same as that of the second chip CB. This can satisfactorily transfer the first multilayer film LA and the second multilayer film LB in the joint process, which will be described later.

In the method of manufacturing the acoustic wave filter device according to the present example embodiment, the first chip CA including the first multilayer film LA is produced in the first chip formation process (steps S11A to S18A), and the second chip CB including the second multilayer film LB is produced in the second chip formation process (steps S11B, S12B, and S15B to S18B). Then, the first chip CA and the second chip CB are joined to the support 10 in the joint process (step S21), the temporary substrates WA and WB are removed in the temporary substrate removal process (Step S22), and accordingly, the first chip CA and the second chip CB are transferred to the support 10.

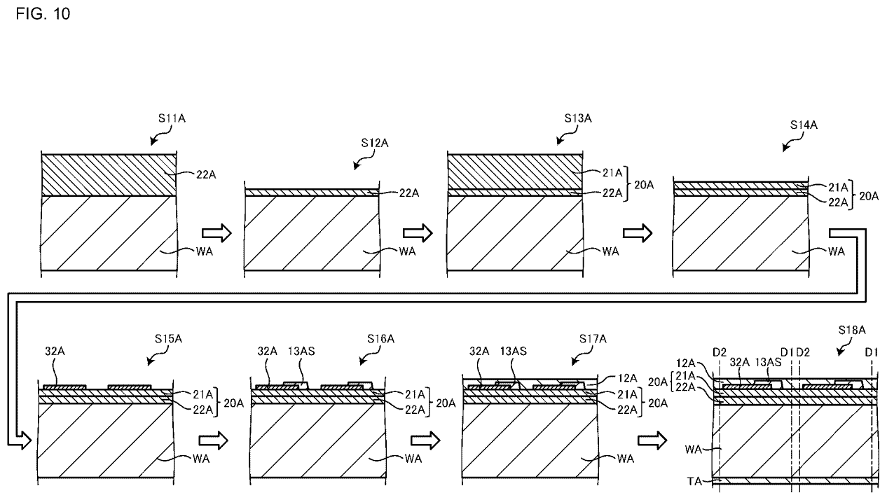

FIG. 10 is a schematic process diagram for describing an example of the first chip formation process in the method of manufacturing the acoustic wave filter device according to the present example embodiment. As illustrated in FIG. 10, the first chip formation process includes a second piezoelectric body bonding process (step S11A), a second piezoelectric film thinning process (step S12A), a first piezoelectric body bonding process (step S13A), a first piezoelectric film thinning process (step S14A), a lower electrode formation process (Step S15A), a sacrificial layer formation process (step S16A), an intermediate layer formation process (step S17A), and a singulation process (step S18A).

In the second piezoelectric body bonding process (step S11A), the second piezoelectric film 22A is bonded to the main surface of the temporary substrate WA. The second piezoelectric film 22A is produced by cutting out an ingot formed by a liquid phase epitaxy (LPE) method, for example.

In the second piezoelectric film thinning process (step S12A), the second piezoelectric film 22A is thinned by grinding, for example. The second main surface 22Ab of the second piezoelectric film 22A is smoothed by polishing, for example.

In the first piezoelectric body bonding process (step S13A), the first piezoelectric film 21A is bonded to the second main surface 22Ab of the second piezoelectric film 22A. Similarly to the second piezoelectric film 22A, the first piezoelectric film 21A is produced by cutting out an ingot formed by the LPE method, for example. In the present example embodiment, the first piezoelectric film 21A is joined such that the polarization orientation differs from that of the second piezoelectric film 22A.

In the first piezoelectric film thinning process (step S14A), the first piezoelectric film 21A is thinned by grinding, for example. The second main surface 21Ab of the first piezoelectric film 21A is smoothed by polishing, for example.

In the lower electrode formation process (step S15A), the pattern formation of the lower electrode 32A is performed on the second main surface 21Ab of the first piezoelectric film 21A by using a method, such as liftoff, for example. At this time, a metal film for wiring lines or the like may be simultaneously formed on the second main surface 21Ab of the first piezoelectric film 21A.

In the sacrificial layer formation process (step S16A), the sacrificial layer 13AS is formed on the second main surface 21Ab of the first piezoelectric film 21A so as to cover a portion of the lower electrode 32A. The sacrificial layer 13AS is made of, for example, zinc oxide.

In the intermediate layer formation process (step S17A), the intermediate layer 12A is formed on the second main surface 21Ab of the first piezoelectric film 21A so as to cover the lower electrode 32A and the sacrificial layer 13AS. The intermediate layer 12A is preferably made of silicon oxide, for example. As a result, in the joint process, which will be described later, the intermediate layer 12A and the intermediate layer 12C can be joined to each other by using hydrophilic coupling, for example. The main surface of the intermediate layer 12A on the opposite side from the first piezoelectric layer 20A is flattened by grinding and then smoothed by polishing, for example. At this time, the surface roughness of the main surface of the intermediate layer 12A on the opposite side from the first piezoelectric layer 20A is preferably, for example, about 1 nm or less in terms of arithmetic average roughness (Ra). This can satisfactorily perform joining between the intermediate layer 12A and the intermediate layer 12C by using, for example, hydrophilic coupling in the joint process, which will be described later.

In the singulation process (step S18A), the temporary substrate WA and the first multilayer film LA are singulated. In the example embodiment in FIG. 10, of the regions between dash-dot lines D1 and dash-dot lines D2, the region in which the functional electrode (lower electrode 32A) is not present is removed and singulation is performed. As a result, the first chip CA including the first multilayer film LA is produced. Upon completion of singulation, an adhesion layer TA is provided on the main surface of the temporary substrate WA on the opposite side from the first multilayer film LA.

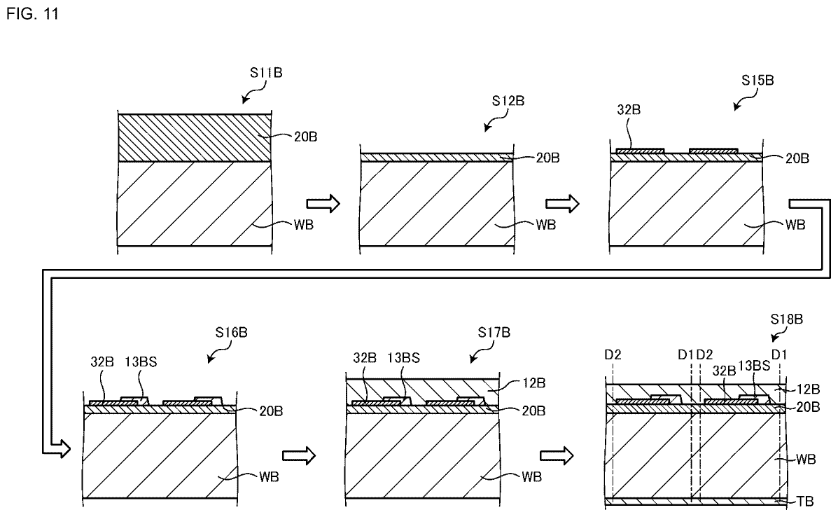

FIG. 11 is a schematic process diagram for describing an example of the second chip formation process in the method of manufacturing the acoustic wave filter device according to the present example embodiment. The second chip formation process includes a piezoelectric layer bonding process (step S11B), a piezoelectric layer thinning process (step S12B), a lower electrode formation process (step S15B), a sacrificial layer formation process (step S16B), an intermediate layer formation process (step S17B), and a singulation process (step S18B).

In the piezoelectric layer bonding process (step S11B), the second piezoelectric layer 20B is bonded to the main surface of the temporary substrate WB.

In the piezoelectric layer thinning process (step S12B), the second piezoelectric layer 20B is thinned by grinding, for example. The second main surface 20Bb of the second piezoelectric layer 20B is smoothed by polishing, for example.

In the lower electrode formation process (step S15B), the pattern formation of the lower electrode 32B is performed on the second main surface 20Bb of the second piezoelectric layer 20B by using a method, such as liftoff, for example. At this time, a metal film for wiring lines or the like may be simultaneously formed on the second main surface 20Bb of the second piezoelectric layer 20B.

In the sacrificial layer formation process (step S16B), the sacrificial layer 13BS is formed on the second main surface 20Bb of the second piezoelectric layer 20B so as to cover a portion of the lower electrode 32B. The sacrificial layer 13BS is made of, for example, zinc oxide.

In the intermediate layer formation process (step S17B), the intermediate layer 12B is formed on the second main surface 20Bb of the second piezoelectric layer 20B so as to cover the lower electrode 32B and the sacrificial layer 13BS. The intermediate layer 12B is preferably made of silicon oxide, for example. As a result, in the joint process, which will be described later, the intermediate layer 12B and the intermediate layer 12C can be joined to each other by using hydrophilic coupling, for example. The main surface of the intermediate layer 12B on the opposite side from the second piezoelectric layer 20B is flattened by grinding and then smoothed by polishing, for example. At this time, the surface roughness of the main surface of the intermediate layer 12B on the opposite side from the second piezoelectric layer 20B is preferably, for example, 1 nm or less in terms of arithmetic average roughness (Ra). This can satisfactorily perform joining between the intermediate layer 12B and the intermediate layer 12C by using hydrophilic coupling in the joint process, which will be described later.

In the singulation process (step S18B), the temporary substrate WB and the second multilayer film LB are singulated. In the example embodiment in FIG. 11, of the regions between dash-dot lines D1 and dash-dot lines D2, the region in which the functional electrode (lower electrode 32B) is not present is removed and singulation is performed. As a result, the second chip CB including the second multilayer film LB is produced. Upon completion of singulation, an adhesion layer TB is provided on the main surface of the temporary substrate WB on the opposite side from the second multilayer film LB.

In the present example embodiment, the intermediate layer 12C is formed on the support substrate 11 before the joint process, which will be described later. The intermediate layer 12C is preferably made of silicon oxide, for example. Next, the surface of the intermediate layer 12C is smoothed. At this time, the surface roughness of the intermediate layer 12C is preferably, for example, about 1 nm or less in terms of Ra. This enables a hydrophilic joint between the intermediate layer 12C of the support substrate 11 and the intermediate layers 12A and 12B of the first and second chips CA and CB in the joint process.

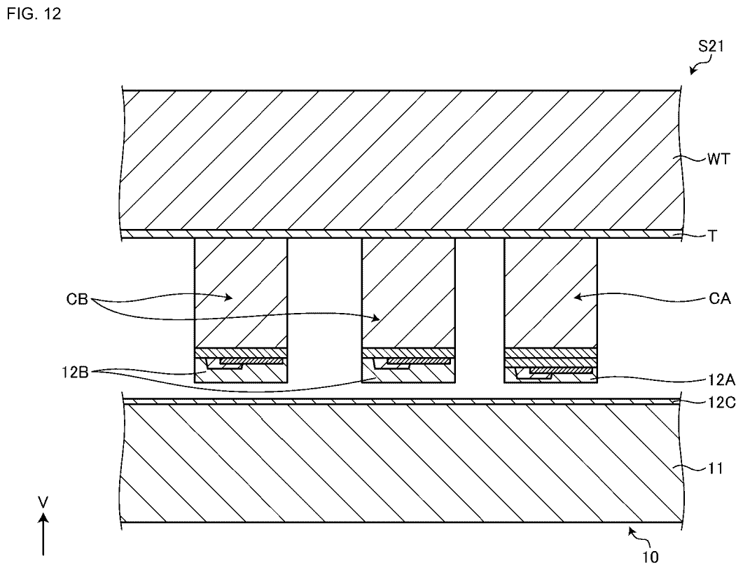

FIG. 12 is a schematic cross-sectional view for describing the joint process in the method of manufacturing the acoustic wave filter device according to the present example embodiment. As illustrated in FIG. 12, in the joint process (step S21), after the first chip CA and the second chip CB are arranged on a transfer substrate WT, the first chip CA and the second chip CB are joined to the support 10. More specifically, the first chip CA and the second chip CB are arranged on the transfer substrate WT via an adhesion layer T such that the first resonator RA and the second resonator RB of the acoustic wave filter device are arranged. At this time, since the disposition of the first chip CA and the second chip CB on the transfer substrate WT directly corresponds to the positions of the first multilayer film LA and the second multilayer film LB on the support substrate 11, the first chip CA and the second chip CB are preferably arranged with high precision. In addition, at this time, the thicknesses of the first chip CA and the second chip CB are the same or substantially the same as each other, and the smoothed intermediate layers 12A and 12B are flush with each other. After that, the intermediate layers 12A and 12B of the first chip CA and the second chip CB are joined to the intermediate layer 12C provided on the support substrate 11. In the present example embodiment, the intermediate layers 12A and 12B and the intermediate layer 12C are bonded to each other at room temperature and heated at, for example, about 150° C., and accordingly, the intermediate layers 12A and 12B and the intermediate layer 12C are joined to each other by using hydrophilic coupling, for example. Since this achieves a firm joint that prevents foreign substances from being mixed into the joint interface, the filter characteristics can be improved. After that, the transfer substrate WT is peeled off and removed from the first chip CA and the second chip CB.

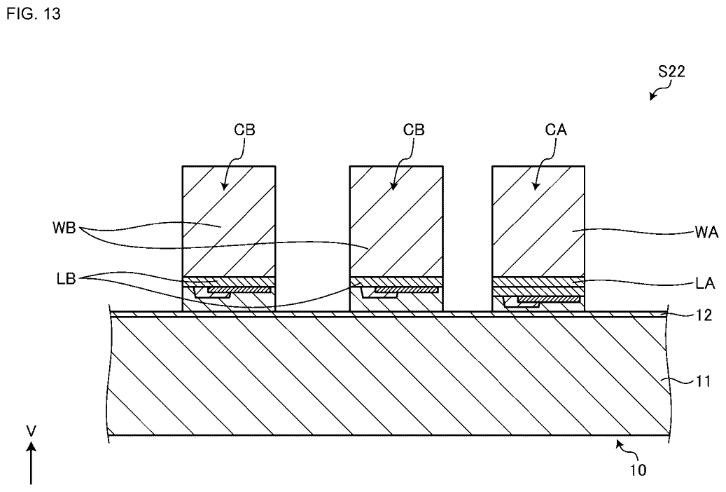

FIG. 13 is a schematic cross-sectional view for describing the temporary substrate removal process in the method of manufacturing the acoustic wave filter device according to the present example embodiment. As illustrated in FIG. 13, in the temporary substrate removal process (step S22), the temporary substrates WA and WB are removed from the first chip CA and the second chip CB. In the present example embodiment, the temporary substrates WA and WB are removed by etching, for example. As a result, the first multilayer film LA and the second multilayer film LB that include different numbers of piezoelectric films can be transferred to the support 10.

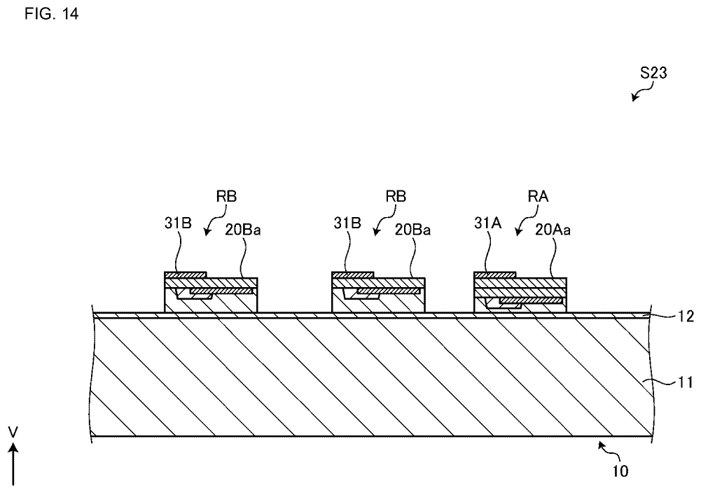

FIG. 14 is a schematic cross-sectional view for describing the upper electrode formation process in the method of manufacturing the acoustic wave filter device according to the present example embodiment. As illustrated in FIG. 14, in the upper electrode formation process (step S23), the upper electrodes 31A and 31B are formed on the first main surfaces 20Aa and 20Ba of the first piezoelectric layer 20A and the second piezoelectric layer 20B, respectively. In the present example embodiment, the upper electrodes 31A and 31B are formed by, for example, liftoff. After the upper electrodes 31A and 31B are formed, a frequency adjustment film, which is not illustrated, is provided at a position that overlaps the excitation regions of the first resonator RA and the second resonator RB in plan view in the V direction.

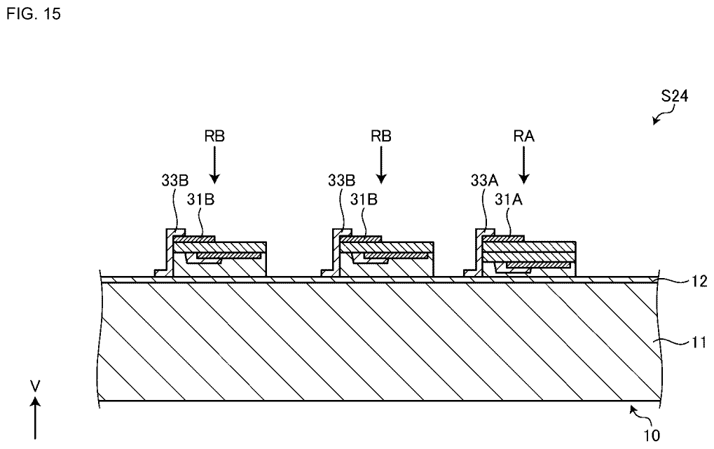

FIG. 15 is a schematic cross-sectional view for describing the first wiring electrode formation process in the method of manufacturing the acoustic wave filter device according to the present example embodiment. As illustrated in FIG. 15, in the first wiring electrode formation process (step S24), the wiring electrodes 33A and 33B are formed so as to be connected to the upper electrodes 31A and 31B, respectively. The wiring electrodes 33A and 33B are formed by, for example, liftoff. As a result, the upper electrodes 31A and 31B are extended by the wiring electrodes 33A and 33B.

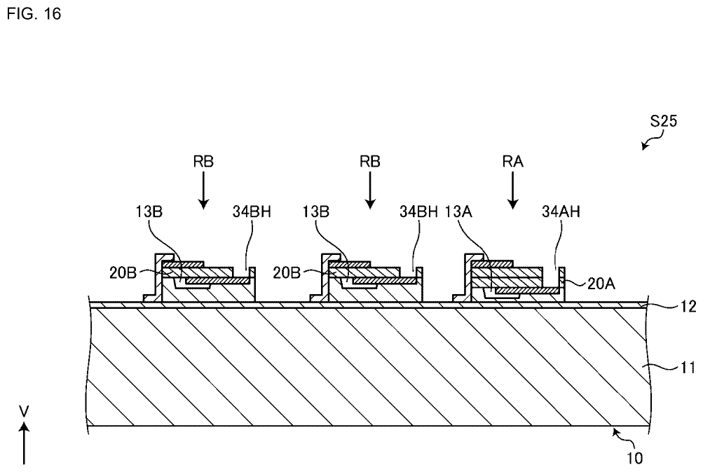

FIG. 16 is a schematic cross-sectional view for describing the space portion formation process in the method of manufacturing the acoustic wave filter device according to the present example embodiment. As illustrated in FIG. 16, in the space portion formation process (step S25), through-holes 20AH and 20BH are formed in the first piezoelectric layer 20A and the second piezoelectric layer 20B, respectively, the sacrificial layers 13AS and 13BS are removed by, for example, etching gas or etching solution being introduced through the through-holes 20AH and 20BH, and accordingly, the space portions 13A and 13B are formed. In the present example embodiment, when the through-holes 20AH and 20BH are formed, the opening windows 34AH and 34BH are simultaneously formed in the first piezoelectric layer 20A and the second piezoelectric layer 20B, respectively, such that the lower electrodes 32A and 32B are exposed through the opening windows 34AH and 34BH. In the present example embodiment, the through-holes 20AH and 20BH and the opening windows 34AH and 34BH are formed by forming a resist pattern and performing dry etching, for example.

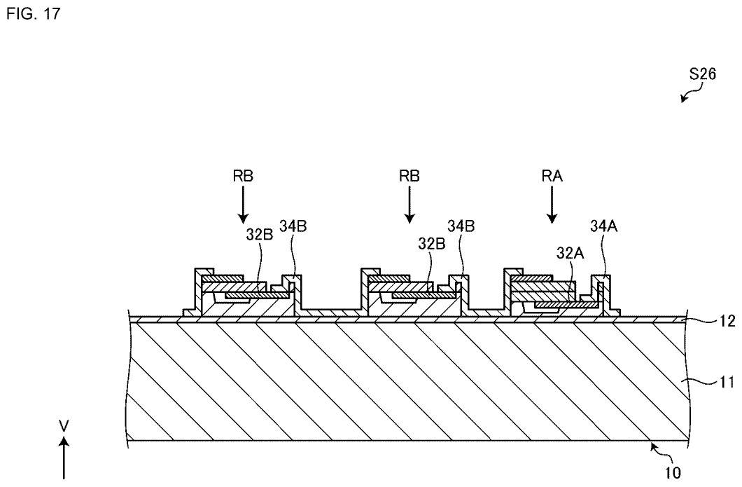

FIG. 17 is a schematic cross-sectional view for describing the second wiring formation process in the method of manufacturing the acoustic wave filter device according to the present example embodiment. As illustrated in FIG. 17, in the second wiring formation process (step S26), the wiring electrodes 34A and 34B are formed in the opening windows 34AH and 34BH, respectively. The wiring electrodes 34A and 34B are formed by, for example, liftoff. As a result, the lower electrodes 32A and 32B are extended by the wiring electrodes 34A and 34B, respectively.

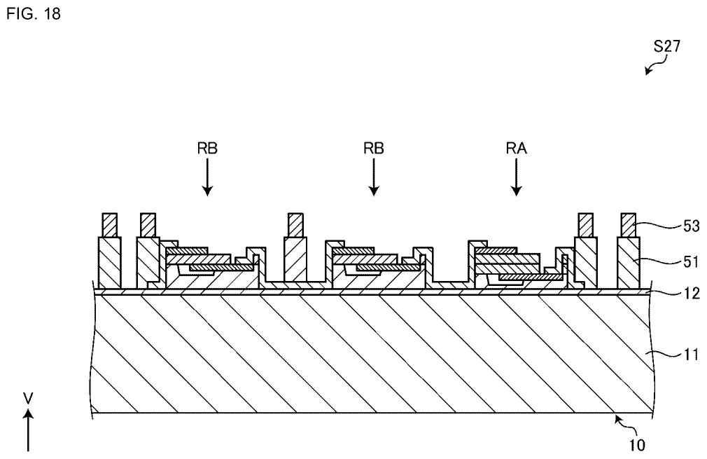

FIG. 18 is a schematic cross-sectional view for describing the support frame formation process in the method of manufacturing the acoustic wave filter device according to the present example embodiment. As illustrated in FIG. 18, in the support frame formation process (step S27), the first lands 51A and 51B are formed, the adhesion layers 53A and 53B are laminated on the first lands 51A and 51B, respectively, and the support frames 50A and the extended electrodes 50B are formed. Here, the first lands 51A and the adhesion layers 53A are formed in a frame shape so as to surround the first resonator RA and the second resonator RB in plan view in the V direction. As a result, the support frames 50A are formed. In addition, the first lands 51B and the adhesion layers 53B are formed so as to be electrically connected to one of the wiring electrodes 33A, 33B, 34A, and 34B. As a result, the extended electrodes 50B are formed. After the support frames 50A and the extended electrodes 50B are formed, the resonance characteristics of the first resonator RA and the second resonator RB are measured by probe measurement, for example. The resonance characteristics of the first resonator RA and the second resonator RB are adjusted by, for example, adjusting the thickness of the frequency adjustment film in accordance with the measurement results. The thickness of the frequency adjustment film is adjusted by, for example, grinding the frequency adjustment film with an ion beam.

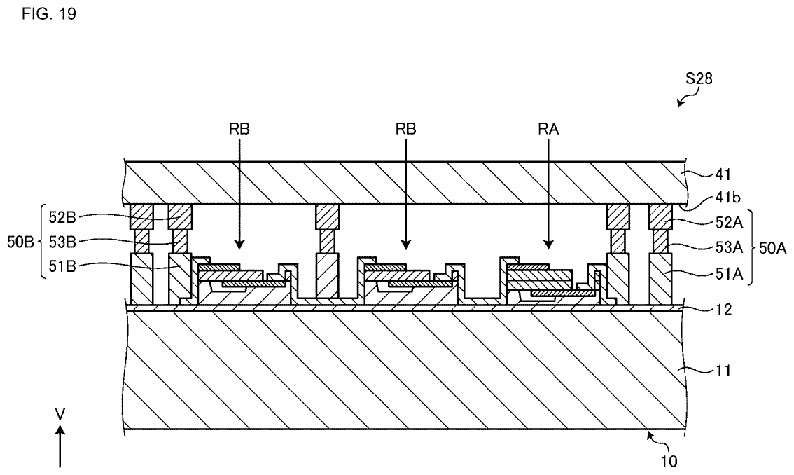

FIG. 19 is a schematic cross-sectional view for describing the sealing process in the method of manufacturing the acoustic wave filter device according to the present example embodiment. As illustrated in FIG. 19, in the sealing process (step S28), the cover substrate 41 is joined to the support 10. More specifically, the second lands 52A and 52B are formed on the cover substrate 41, the adhesion layers 53A and 53B are laminated on the second lands 52A and 52B, respectively, and the support 10 and the cover substrate 41 are closed by adhering the adhesion layers 53A and 53B to each other to seal the space between the support 10 and the cover 40. In the present example embodiment, the first lands 51A and 51B are joined to the second lands 52A and 52B, respectively, by, for example, thermal bonding. In addition, after the cover substrate 41 is joined to the support 10, the cover substrate 41 is thinned.

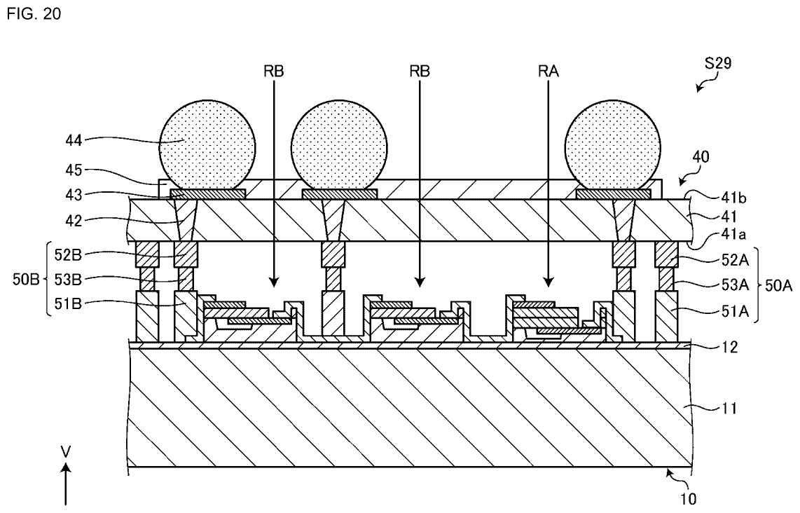

FIG. 20 is a schematic cross-sectional view for describing the bump formation process in the method of manufacturing the acoustic wave filter device according to the present example embodiment. As illustrated in FIG. 20, in the bump formation process (step S29), the through-electrodes 42, the underbump metals 43, the solder balls 44, and the insulation layer 45 are formed. The through-electrodes 42 are provided in through-vias of the cover substrate 41 that are provided at positions that overlap the second lands 52B in a plan view in the V direction. The underbump metals 43 are provided on the first main surface 41a of the cover substrate 41 so as to be in electrical contact with the through-electrodes 42. The solder balls 44 are provided so as to be in electrical contact with the underbump metals 43. The insulation layer 45 is provided on the first main surface 41a of the cover substrate 41 so as to cover the underbump metals 43.

Upon completion of the processes described above, the acoustic wave filter device 1 according to the present example embodiment can be manufactured by singulating the support 10 and the cover substrate 41. The processes described above are merely schematic and can be changed as appropriate.

As described above, the method of manufacturing the acoustic wave filter device according to the present example embodiment is a method of manufacturing an acoustic wave filter device including a plurality of resonators, and the method includes the first chip formation process of forming the first chip including the first piezoelectric layer and the temporary substrate, the second chip formation process of forming the second chip including the second piezoelectric layer and the temporary substrate, the joint process of joining the first chip and the second chip to the main surface of the support including the support substrate having the thickness in the first direction, and the temporary substrate removal process of removing the temporary substrates of the first chip and the second chip joined to the support. The plurality of resonators include the first resonator that is provided in the first piezoelectric layer and the second resonator that is provided in the second piezoelectric layer. The first piezoelectric layer includes the first piezoelectric film and the second piezoelectric film laminated on the first piezoelectric film. The polarization direction of the first piezoelectric film differs from the polarization direction of the second piezoelectric film. The number of piezoelectric films included in the second piezoelectric layer is smaller than the number of the piezoelectric films included in the first piezoelectric layer. As a result, since the area of the functional electrodes of the second resonator can be reduced while the resonance characteristics of the first resonator are improved, the size of the acoustic wave filter device can be reduced while the resonance characteristics of the acoustic wave filter device are improved.

Preferably, for example, in the joint process, the first piezoelectric layer and the second piezoelectric layer are joined to the support via an intermediate layer made of a dielectric. As a result, the profile of the acoustic wave filter device can be reduced while the frequency characteristics are maintained good, and accordingly, the size of the acoustic wave filter device can be further reduced while the resonance characteristics of the acoustic wave filter device are improved.

Here, examples of example embodiments of the present invention will be described. The present invention is not limited to the examples described below.

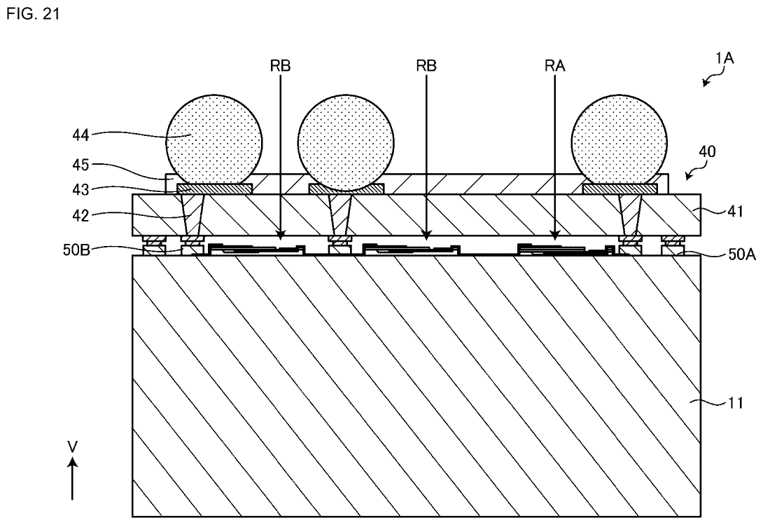

FIG. 21 is a schematic cross-sectional view illustrating an acoustic wave filter device according to an example of an example embodiment of the present invention. In an acoustic wave filter device 1A according to the example illustrated in FIG. 21, the thickness of the support substrate 11 is about 200 μm, the thickness of the support frame 50A is about 10 μm, the thickness of the cover substrate 41 is 30 about μm, the height of the solder balls 44 from the main surface of the cover substrate 41 is about 60 μm, the maximum thickness of the intermediate layer 12 is about 1 μm, the thickness of the first piezoelectric film and the second piezoelectric film is about 0.5 μm, the thickness of the functional electrodes is about 0.3 μm, and the thickness of the wiring electrodes is about 1 μm. As illustrated in FIG. 21, when the first piezoelectric layer 20A and the second piezoelectric layer 20B are very thin films with respect to the support substrate 11, the gap between the cover substrate 41 and the support substrate 11 can be significantly reduced by joining the first multilayer film LA and the second multilayer film LB to the support substrate 11 without the intervention of the substrate. As a result, the profile and the size of the acoustic wave filter device 1A can be reduced.

The example embodiments described above are provided to facilitate the understanding of the present invention and are not intended to limit the present invention. The present invention can be changed or improved without deviating from the scope and spirit thereof and includes equivalents thereof.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave filter device including a plurality of resonators, the acoustic wave filter comprising:
a support including a support substrate with a thickness in a first direction;
a first piezoelectric layer on a main surface of the support;
a second piezoelectric layer at a different position from the first piezoelectric layer on the main surface of the support; and
functional electrodes of the plurality of resonators on the first piezoelectric layer and the second piezoelectric layer; wherein
the plurality of resonators include a first resonator in the first piezoelectric layer and a second resonator in the second piezoelectric layer;
the first piezoelectric layer includes a first piezoelectric film and a second piezoelectric film laminated on the first piezoelectric film;
a polarization direction of the first piezoelectric film differs from a polarization direction of the second piezoelectric film; and
a number of piezoelectric films included in the second piezoelectric layer is smaller than a number of the piezoelectric films included in the first piezoelectric layer.

2. The acoustic wave filter device according to claim 1, wherein
the first resonator includes a resonator with a highest resonant frequency of the plurality of resonators; and
the second resonator includes at least one resonator with a lower resonant frequency than the resonator with the highest resonant frequency.

3. The acoustic wave filter device according to claim 1, wherein
the first resonator includes a resonator with a lowest resonant frequency of the plurality of resonators; and
the second resonator includes at least one resonator with a higher resonant frequency than the resonator with the lowest resonant frequency.

4. The acoustic wave filter device according to claim 1, wherein
the first resonator includes a resonator to which a highest power is applied of the plurality of resonators; and
the second resonator includes a resonator to which a lower power is applied than the resonator to which the highest power is applied.

5. The acoustic wave filter device according to claim 1, further comprising:
a transmission filter; and
a reception filter; wherein the first resonator includes a resonator on a path that connects an input terminal and an output terminal of the transmission filter to each other, that is connected to the input terminal of the transmission filter; and
the second resonator includes at least one resonator on a path that connects the first resonator and the output terminal of the transmission filter to each other or on a path that connects an input terminal and an output terminal of the reception filter to each other.

6. The acoustic wave filter device according to claim 1, further comprising:
an input terminal, an output terminal, a series arm that connects the input terminal and the output terminal to each other, and a parallel arm that connects, to each other, ground and at least one of the input terminal, the output terminal, or a node of the series arm; wherein
the first resonator includes at least one of resonators in the series arm; and
the second resonator includes at least one of resonators in the parallel arm.

7. The acoustic wave filter device according to claim 1, further comprising:
an intermediate layer, made of a dielectric, between the main surface of the support substrate and the first and second piezoelectric layers.

8. The acoustic wave filter device according to claim 7, wherein a material of the intermediate layer has a lower dielectric constant than materials of the support substrate, the first piezoelectric layer, and the second piezoelectric layer.

9. The acoustic wave filter device according to claim 1, wherein a thickness of each of the first and second piezoelectric layers is about 1 μm or less.

10. The acoustic wave filter device according to claim 1, wherein each of the first and second piezoelectric films includes lithium niobate, lithium tantalate, or quartz.

11. The acoustic wave filter device according to claim 1, wherein the polarization direction of the first piezoelectric film differs from a polarization direction of the second piezoelectric film by about 180°.

12. A method of manufacturing an acoustic wave filter device including a plurality of resonators, the method comprising:
forming a first chip including a first piezoelectric layer and a first temporary substrate;
forming a second chip including a second piezoelectric layer and a second temporary substrate;
joining the first chip and the second chip to a main surface of a support including a support substrate with a thickness in a first direction; and
removing the first and second temporary substrates of the first chip and the second chip joined to the support; wherein the plurality of resonators include a first resonator in the first piezoelectric layer and a second resonator in the second piezoelectric layer;
the first piezoelectric layer includes a first piezoelectric film and a second piezoelectric film laminated on the first piezoelectric film;
a polarization direction of the first piezoelectric film differs from a polarization direction of the second piezoelectric film; and
a number of piezoelectric films included in the second piezoelectric layer is smaller than a number of the piezoelectric films included in the first piezoelectric layer.

13. The method of manufacturing an acoustic wave filter device according to claim 12, wherein, in the joining the first chip and the second chip to the main surface of the support, the first piezoelectric layer and the second piezoelectric layer are joined to the support via an intermediate layer made of a dielectric.

14. The method of manufacturing an acoustic wave filter device according to claim 12, wherein
the first resonator includes a resonator with a highest resonant frequency of the plurality of resonators; and
the second resonator includes at least one resonator with a lower resonant frequency than the resonator with the highest resonant frequency.

15. The method of manufacturing an acoustic wave filter device according to claim 12, wherein
the first resonator includes a resonator with a lowest resonant frequency of the plurality of resonators; and
the second resonator includes at least one resonator with a higher resonant frequency than the resonator with the lowest resonant frequency.

16. The method of manufacturing an acoustic wave filter device according to claim 12, wherein
the first resonator includes a resonator to which a highest power is applied of the plurality of resonators; and
the second resonator includes a resonator to which a lower power is applied than the resonator to which the highest power is applied.

17. The method of manufacturing an acoustic wave filter device according to claim 13, wherein a material of the intermediate layer has a lower dielectric constant than materials of the support substrate, the first piezoelectric layer, and the second piezoelectric layer.

18. The method of manufacturing an acoustic wave filter device according to claim 12, wherein a thickness of each of the first and second piezoelectric layers is about 1 μm or less.

19. The method of manufacturing an acoustic wave filter device according to claim 12, wherein each of the first and second piezoelectric films includes lithium niobate, lithium tantalate, or quartz.

20. The method of manufacturing an acoustic wave filter device according to claim 12, wherein the polarization direction of the first piezoelectric film differs from a polarization direction of the second piezoelectric film by about 180°.
